(19) United States
(12) Patent Application Publication
(10) Pub. No.: US 2014/0262753 A1
(43) Pub. Date: Sep. 18, 2014

(54) SEPARATION OF FUNCTION-BASED THIN-FILM DEPOSITION SYSTEMS AND METHOD FOR SYNTHESIS OF COMPLEX MATERIALS

(71) Applicant: Troy W. Barbee, JR., Palo Alto, CA (US)

(72) Inventor: Troy W. Barbee, JR., Palo Alto, CA (US)

(21) Appl. No.: 13/843,252

(22) Filed: Mar. 15, 2013

(51) Int. Cl. C23C 14/35; H01J 37/34

(52) U.S. Cl. CPC C23C 14/35; H01J 37/3411
USPC 204/192.15; 204/298.25; 204/192.12

(57) ABSTRACT

A thin-film deposition system and method based on separating the function of multiple material sources by locating the sources in separate chambers partitioned by a partition wall, and providing a substrate conveyer, such as a rotating platform, to cyclically convey a substrate between the partitioned chambers so that the materials from the separated sources are serially introduced to the substrate per cycle in isolation of each other for layer-by-layer deposition and/or reaction on the substrate.

### FEDERALLY SPONSORED RESEARCH OR DEVELOPMENT

The United States Government has rights in this invention pursuant to Contract No. DE-AC52-07NA27344 between the United States Department of Energy and Lawrence Livermore National Security, LLC for the operation of Lawrence Livermore National Laboratory.

### TECHNICAL FIELD

This patent document relates to thin film deposition and fabrication methods, and in particular to a system and method of thin film deposition which separates the introduction of materials to a deposition surface in isolation of each other, to prevent cross contamination between the various material sources and improve process performance and product quality.

### BACKGROUND

Synthesis of thin films (e.g. <200 nm), thick films (e.g. 200-500 nm) and foils (e.g. >5000 nm) of binary, ternary, quaternary, and higher order composition, as well as complex layered structures of strongly dissimilar materials by existing deposition methods (e.g. physical vapor deposition (PVD)) is commonly limited in terms of rate of manufacture, cross-contamination generated failures, particle generation-limiting material performance, the inability to maintain tight composition requirements, as well as physical limitations of the implemented apparatus. Moreover, material source contamination; limited substrate area; difficulty in fabricating material of the correct composition; degradation of performance and product yields by fabrication process-generated particle contamination; and control of the substrate temperature during long processing runs, are also problematic. For reactive magnetron sputter deposition of refractory oxides in particular, known limitations include low deposition rates and process yield; sputter target contamination (due to reactive gas delivery at site directly in front of sputter gun source); stable control of the reaction atmosphere in the deposition chamber; degradation of the refractory oxide deposit due to flaws introduced by sputter source arcing and contamination by spalling of oxide film deposited generally in the chamber away from the active substrates; etc. For example, the impact of flaws in dielectric material used for capacitors can dramatically degrade capacitor performance.

Efforts to overcome said limitations have included, for example, using better than CLASS 50 clean room for processing facility, implementing thermal control by interrupting the process to allow system cool down, implementing RF sputter deposition (which allowed somewhat higher processing rates but also increase thermal load on system and equipment complexity, processing gas load on the sputter system. Despite such efforts there remains however a need to improve and enhance manufacture rate, control of composition, control of contamination, elimination of minimization of the generation of particles and process generated debris.

### SUMMARY

One aspect of the present invention includes a thin-film deposition system comprising: first and second chambers partitioned from each other by a partition wall; a first material source arranged to introduce a first material to a substrate as it passes through the first chamber; a second material source arranged to introduce a second material to a substrate as it passes through the second chamber; and a substrate conveyer adapted to cyclically convey a substrate between the first and second chambers so that the first and second materials are serially introduced to the substrate per cycle in isolation of each other for layer-by-layer deposition and/or reaction on the substrate.

Another aspect of the present invention a thin-film deposition method comprising: providing first and second chambers partitioned from each other by a partition wall; a first material source arranged to introduce a first material to a substrate as it passes through the first chamber; and a second material source arranged to introduce a second material to a substrate as it passes through the second chamber; and cyclically conveying a substrate between the first and second chambers so that the first and second materials are serially introduced to the substrate per cycle in isolation of each other for layer-by-layer deposition and/or reaction on the substrate.

Generally, the present invention is directed to a system and method designed to separate the function of the various material (e.g. elemental) sources used to deposit material onto a substrate, by separating fixed-site sources for the individual film/foil components into partitioned chambers which are adapted to prevent cross-flow between chambers (and optionally also providing conduits (e.g. “chimneys”) for channeling material to the substrate), and cyclically moving a substrate between the partitioned chambers to control exposure to the component material elements. Various material sources may be used, such as for example a magnetron source, a gas inlet (e.g. oxygen or nitrogen), and is not limited to any particular device, apparatus, or methodology for depositing materials, elemental or otherwise. In any case, and arranged in this manner, the system and method is capable of enhanced manufacture rate, control of composition, control of contamination, elimination of minimization of the generation of particles and process generated debris. For example, in a reactive deposition process, the system is configured to separate the oxidation reaction zone from the sputtering target surface thus maintaining a clean non-contaminating sputter target at all times during the process, and to transport the active substrate from the magnetron source located in one partitioned chamber, to the reactive gas site in another partitioned chamber. With this arrangement, increases in manufacturing throughput in excess of a factor of ten and as high as fifty have been observed.

In an example embodiment, such an arrangement may be used to perform atom-by-atom combinatorial and high-throughput synthesis of materials (via reactive or non-reactive process), such as for the development of new classes of complex materials. Molecular oxygen is typically supplied as reactive gas for refractory oxide synthesis. As disclosed in “Controlled Reactive Sputter Synthesis of Refractory Oxides”, by Barbee et al in J. Electrochem. Soc. (1984), for molecular oxygen, the chemisorption sticking coefficient is one part in 50,000 (i.e. ≈0.00002), and much smaller for molecular nitrogen. In contrast, the chemisorption sticking coefficient of these two gases in atomic form are increased by a factor greater than 20,000, e.g. to 0.6 relative to that for molecular oxygen in the oxidation of metals, which greatly increases process control, and decreases temperature dependence of the process above room temperature. For example, in a reactive sputter deposition system, the dramatically increased reactivity of a reactive gas (e.g oxygen or nitrogen) in atomic form can be used to minimize or eliminate process-generated contamination, substantially increase refractory oxide deposition rates and to facilitate a high level of stoichiometry control.

The system and method of the present invention can provide some specific advantages to reactive sputter deposition process. For example, the deposition rate of the refractory oxide can be determined by the intrinsic sputter yield of the metallic target. The oxidation state or composition of the refractory oxide film can also be independently controlled at a level that, in principle, can approach mono-layer by mono-layer. (In the embodiment here a monolayer of metal atoms is deposited onto a substrate that is then transported to an activated oxygen environment in which it is fully oxidized. It then returns to the metal sputter deposition source to receive a new coating of elemental metal etc. The activated oxygen source will be microwave or plasma generated and will increase the chemisorption sticking coefficient by factors of 5000 to 10,000 enabling very high refractory oxide deposition rates as well as exquisite composition control.) Also, very large substrate areas can be coated resulting in an increase in the effective refractory oxide deposition rate. The concept here is that very high metal deposition rates can be used given the substrate is transported through the deposition field of the sputter gun at a rate limiting the layer thickness deposited to a near mono-layer scale. Typical oxide rates are on the order of 0.5 to 1.0 nm/sec. for single substrate systems. In this embodiment an increase in effective substrate area in a simple 33 inch diameter vacuum tank greater than a factor of five is possible with. And in a multi-sputter gun capable deposition system complex film compositions as well as layered structures of significantly dissimilar materials can be synthesized with control at the sub nano-meter scale.

The system and method of the present invention may be used to synthesize high performance complex and simple dielectrics, binary, ternary, quaternary and higher order compounds (e.g. oxides, nitrides, carbides etc.) composed of elements including at least 84 of the 92 naturally occurring elements, defect free large area complex multi-component materials in thin film, thick films, and foil form, with such materials having applications ranging from passive and active electronic devices, optics for hard and soft X-rays, UV, extreme UV, visible, infrared, etc., protective coatings, hard coatings, wear-resistant coatings, etc. Primary impact in areas of capacitor dielectric materials manufacturing and development of new dielectric materials. Also, may be used for atomic layer by atomic layer synthesis of materials of highly reactive components that make initial studies and/or application specific fabrication very difficult. Fabrication of very high performance quarter wave stacks for high power laser optics applications relevant to industrial and national security priorities. Interfacial control at the atomic sub-monolayer/monolayer level for engineered high performance optical quarter wave stacks as well as hyper-spectral applications. Fabrication of combined microstructure very high-resolution structures for hyper-spectral applications and scientific programs. Specific applications to ecological space based technologies. Interface control for high added value materials fabrication. Potential for this technology to be a primary tool in the development of multi-component materials in response to theoretical modeling predictions as well as meeting the need for experimental guidance for such theoretical modeling. Example application: atom by atom processes for manufacture of high performance-high energy density dielectric materials for capacitor applications.

### BRIEF DESCRIPTION OF THE DRAWINGS

FIGS. 1A and 1B show schematic views of a general embodiment of the thin film deposition system and method of the present invention, and particularly shown cyclical motion of the substrate between partitioned chambers.

FIG. 2 shows a perspective view of a first example embodiment of the thin film deposition system and method of the present invention, shown having two partitioned chambers in which material sources are positioned, and a rotating platform which passes a substrate between the chambers.

FIG. 3 shows a schematic view of a second example embodiment of the thin film deposition system and method of the present invention, shown having two chambers partitioned by a partition having a flow channel therein for evacuating both chambers so as to prevent cross-flow therebetween.

FIG. 4 shows a schematic view of a third example embodiment of the thin film deposition system and method of the present invention, shown having two chambers partitioned by a partition having a flow channel therein through which an inert gas may be pumped into the chambers so as to prevent cross-flow therebetween.

### DETAILED DESCRIPTION

Turning now to the drawings, FIGS. 1A and 1B show schematic views of a general embodiment of the thin film deposition system and method of the present invention, generally indicated at 10. The system is shown having a first chamber 16 and a second chamber 15 partitioned from each other by a partition wall shown at 14. While only two chambers are shown partitioned by a single partition wall, it is appreciated that additional partitions may be also provided to partition additional chambers in a similar manner. In any case, the partition wall 14 is particularly shown suspended from an upper support 13 which may for example be an upper wall of a frame or encasement structure. Positioned as such, it is appreciated that the partition wall does not seal off the chambers from each other since the chambers are in communication with each other near the lower end of the partition. While the chambers are shown schematically in FIGS. 1A and 1B as not otherwise contained or enclosed, it is appreciated that the system includes chamber walls to enclose a volume that is generally isolated and enclosed except with respect to communication between chambers at the lower ends of the partition. And a substrate conveyer 19 is also shown provided and adapted to cyclically convey a substrate 20 between the first 16 and second 15 chambers so that the first and second materials from the two chambers are serially introduced to the substrate 20 per cycle in isolation of each other for layer-by-layer deposition and/or reaction on the substrate. While shown schematically in FIGS. 1A and 1B, the substrate conveyor may be particularly constructed to bound the lower ends of all of the chambers (see for example FIG. 2), so that the only access into the chambers is from below the partition wall 14 or walls.

The system 10 is also shown having a first material source 12 positioned in the first chamber 16 and also fixedly suspended from the upper support 13, and a second material source 11 positioned in the second chamber 15 and also fixedly suspended from the upper support 13. As described in the Summary, the two material sources shown may be various types of sources for introducing various types of materials. For example the first material source 12 may be a magnetron sputter source for sputtering metal atoms (e.g. Zr, Nb, Hf, etc.) on a substrate passing into and through the chamber 16, and the second material source 11 may be an oxygen source (e.g. ECR microwave activated oxygen source) with an inlet arranged to introduce oxygen to the substrate passing into and through the chamber 15. Similar to the partition walls described above, additional material sources may be provided (not shown) positioned in additional partitioned chambers to provide additional separation of functionality to the system 10.

Furthermore, the system 10 is also shown having a channeling structure 18 (e.g. “chimney”) connected to the first source 12, to receive material from the source, and which functions to channel, guide, direct, carry, conduct, rout the material to a channel structure outlet (positioned adjacent the substrate conveyor 19) where it is discharged/expelled/emitted out of the channel structure to a substrate passing through the chamber. The second source 11 is similarly shown having a second channeling structure 17, or chimney, connected to receive material from the second source 11, to channel, guide, direct, carry, conduct, rout the material to a channel structure outlet (also positioned adjacent the substrate conveyor 19) where it is discharged/expelled/emitted out of the channel structure to a substrate passing through the chamber. The chimneys function to contain, for example, the sputtered metal atoms that would deposit (on a substrate), outside of, for example, the desired oxygen reaction zone in the adjacent chamber. In an example embodiment, argon sputter gas may be injected within this “chimney” to isolate the metal sputter target from the highly reactive atomic oxygen. In any case, the use of chimneys in addition to the partitioned chambers serves to further isolate and prevent cross-contamination of materials in adjacent chambers.

FIGS. 1A and 1B together also illustrate a general case of cyclical conveyance of the substrate between the chambers, which is key to the controlled deposition/reaction process of the present invention. In particular, FIG. 1A shows the substrate 20 conveyed to first chamber 16 (as indicated by arrow 21) where it is exposed to the material introduced by first source 12 so that the material (i.e. a thin layer, such as an atomic monolayer) is deposited on the substrate or previously deposited material layer, or reacted with the previously deposited material layer. Then in FIG. 1B, the substrate is shown transported (e.g. shuttled, rotated, or otherwise displaced or moved) to chamber 15 (as indicated at arrow 22) where it is exposed to the material introduced by source 11 so that the material (i.e. also a thin layer, such as an atomic monolayer) is deposited or reacted with the deposited material (or formed compound) from chamber 16. This cycle may be repeated continuously until a specific desired composition or material thickness is produced on the substrate 20. It is appreciated that the cyclical conveyance of the substrate between the chambers is performed by passing underneath the partition wall 14. In this manner, the substrate conveyer 19 is adapted to cyclically convey a substrate between the chambers so that the first, second, and additional materials are serially introduced to the substrate per cycle in isolation of each other for layer-by-layer deposition and/or reaction on the substrate.

In an example case of producing a metal oxide, the cycle would being with passing a substrate first into the first chamber 12 where a metal layer is deposited (e.g. channeled form the source 12 to the substrate 20 via chimney 18, followed by passing the metal-coated substrate into the second chamber 15 where oxygen from an oxygen source 11 is channeled to the substrate 20 via chimney 17 to oxidize the metal layer, and cyclically continuing the substrate conveyance until a desired material is formed. The benefit of moving the substrate from outlet to outlet is that it naturally prepares the surface (i.e. top layer) of the substrate for the next cycle. For example, unreacted oxygen atoms remaining on the substrate may be removed simply due to substrate motion into the next chamber. In some examples (e.g. fabrication of aluminum antimonide), a heater may be additionally provided underneath the substrate and carried by the substrate conveyor to evaporate excess material (e.g. antimony) prior to passing it to the next chamber for next cycle processing.

FIG. 2 shows an example embodiment of the thin film deposition system of the present invention, generally indicated at 30, and having representative first and second sources 31 and 32, respectively. Chimneys are also shown connected to the sources, such as chimney 38 with source 32, channeling material directly to the surface of the passing substrate 40. In this case, the substrate conveyor is shown as a rotating platform (i.e. substrate mounting table) 39, with the substrate 40 positioned at a substrate mounting area that is radially spaced from a rotational axis of the platform, i.e. at an outer/peripheral position of the platform 39 to “orbit” about the rotational axis of the table. In this manner the substrate may be cyclically conveyed between the first and second chambers when the platform is rotated about the rotational axis, as shown by arrow 41. Rotation rate of substrate table is not limited to any particular range (e.g. 50-500 rpm or higher). However, experiments have been run having instrument capability of a 3 second period (20 rpm). The effective deposition rate originally estimated was based on a rotation period of 1 sec (60 rpm). Also shown in FIG. 2 is a partition wall 34 which partitions two chambers 36 and 35. And an open-top cylindrical enclosure 42 is also shown illustrating an example method of enclosing the chambers 36 and 35. In particular, the combined structure of the upper support 33, the rotating platform 39, as well as the partition wall and sources, may be adapted to be lowered into the cylindrical enclosure 42 so that the partitioned chambers 35 and 36 may be enclosed in part by the enclosure 42, for operation.

In a reactive deposition process operated in the system of the present invention, the second material provided by the second material source is of a type known to react with the first material so that each cycle forms a compound layer on the substrate. In particular, the first and second material sources may be particularly arranged in the cycle so that the first material is one capable of being deposited on a surface, e.g. a metal, and the second material may be, for example, a reactive gas, which because it may not itself be capable of being deposited directly, follows the first material in the cycle. For example, in the case where the first material provided by the first material source is a metal, and the second material provided by the second material source is oxygen or nitrogen, each cycle deposits on the substrate a metal layer followed by exposure to the oxygen or nitrogen to react with the metal layer to form an oxide or nitride layer, respectively. Additionally, where the first material provided by the first material source is an atomic metal, and the second material provided by the second material source is atomic oxygen or nitrogen, so that the oxide or nitride layer formed per cycle is a fully oxidized or nitridized atomic monolayer. Controlling against cross-flow of the reactive second material into the first chamber is particularly important in such reactive process system to prevent contamination of the first material source and/or deposited first material on the substrate.

FIG. 3 shows another example embodiment of the system of the present invention, generally indicated at 50, and having a similar arrangement as described in FIGS. 1A and 1B. In particular, two representative sources 52 and 51 are shown connected to chimneys 58 and 57, respectively, and positioned in respective chambers 56 and 55 that is partitioned by partition wall 54. A rotating platform 59 similar to FIG. 2 is also shown provided to rotatably convey the substrate 60 cyclically between the chambers. In this embodiment, the partition wall 54 is also shown having an internal flow conduit 61 in communication with the chambers 56 and 57 at the lower end of the partition wall near the platform 59, and also in communication with a vacuum pump 63 or other evacuation source. In particular, the vacuum pump 63 operates to pump the two chambers simultaneously at the lower end of the partition, as indicated by arrow 64 so that material present in the chambers is flowed out of the respective chambers, into the partition wall and out of the system, whereby material is prevented from cross-flowing into an adjacent chamber and contaminating the material source and/or the deposited material on the substrate.

FIG. 4 shows still another example embodiment of the system of the present invention, generally indicated at 70, and having a similar arrangement as described in FIG. 3. However, the difference in FIG. 4 with respect to FIG. 3 is that instead of a vacuum source for drawing material out of the chambers, an inert gas source 65 is connected to the partition wall 54 to flow inert gas, e.g. argon, into the chambers, as indicated by arrow 66 into chamber 56 and arrow 62′ into chamber 55. This arrangement is also intended as an alternative method of preventing cross-flow between adjacent chambers and preventing contamination of the material source and/or the deposited material on the substrate.

### Example

In one experimental setup of the system, a magnetron sputter deposition system was used, together with an activated oxygen source, to synthesize refractory ZrO2. In this test system zirconium metal was sputter deposited using a 6 inch inner diameter chimney collimated a 3 inch planar magnetron gun. The substrate was rotated at 20 rpm, and the Zr deposition rate empirically calibrated to deposit 2.65 Å Zr in each metal layer. Activated oxygen was delivered to each of these Zr metal layers by a 6 inch inner diameter Pyrex pipe that collimates the activated oxygen output of an ECR Microwave source. And substrates centered on a 9.5 inch radius were mounted on a rotating table that passes in front of the sputtered metal atom source and then the atomic oxygen source resulting in the formation of the refractory oxide.

Each pass before the metal atom source produced a metal atom layer of 0.2 or 0.263 nm thickness in the case of Zirconium, and reacted with atomic oxygen to form ZrO₂ would result in oxide layers 1.486 times the metal atom layer thickness. A 0.2 nm thick Zr layer has 8.57×10¹⁴ atoms/cm² thus requiring at least 1.71×10¹⁵ oxygen atoms/cm² for formation of ZrO₂. It was assumed that only 10% of the atomic oxygen react with the Zr atoms, and also accounting for the 0.15 efficiency of the microwave ECR Atomic Oxygen source used in this example, this 0.2 nm thick film required 1.2×10¹⁶/cm² atomic oxygen atoms for complete formation of ZrO₂. This in turn required 5.6×10¹⁶/cm² oxygen molecules for full oxidation of this 0.2 nm thick Zr layer. Oxygen flow was 2.24×10⁴ cm³/mol at STP. Therefore, for 20 sccm O₂ flow, (20/2.24×10⁴) 6.023×10²³=5.37×10²° O₂/min=8.9×10¹⁸ O₂/sec. The area exposed to this Oxygen flow was about 75 cm². And the exposure time was about 0.3 sec. Therefore, the 0.2 nm Zr layer saw (8.9×10¹⁸)/250=3.5×10¹⁶ O₂/cm². It is believed that cutting back on the Zr layer thickness may enable an increase in the breakdown strength of the formed material from ≈3 MV/cm to >5 MV/cm.

I claim:

1. A thin-film deposition system comprising:
first and second chambers partitioned from each other by a partition wall;
a first material source arranged to introduce a first material to a substrate as it passes through the first chamber;
a second material source arranged to introduce a second material to a substrate as it passes through the second chamber; and
a substrate conveyer adapted to cyclically convey a substrate between the first and second chambers so that the first and second materials are serially introduced to the substrate per cycle in isolation of each other for layer-by-layer deposition and/or reaction on the substrate.

2. The thin film deposition system of claim 1,
wherein the substrate conveyor includes a rotatable platform having a substrate-mounting area radially spaced from a rotational axis so that a substrate positioned on the substrate-mounting area is cyclically conveyed between the first and second chambers when the platform is rotated about the rotational axis.

3. The thin film deposition system of claim 1,
further comprising a first channeling structure positioned in the first chamber and connected to receive the first material from the first material source and channel the first material to an outlet of the first channeling structure adjacent the substrate conveyor; and a second channeling structure positioned in the second chamber and connected to receive the second material from the second material source and channel the second material to an outlet of the second channeling structure adjacent the substrate conveyor,
wherein the substrate conveyer is adapted to cyclically convey a substrate across the outlets of the channeling structures so that the first and second materials are serially introduced directly to the substrate per cycle in further isolation of each other for layer-by-layer deposition and/or reaction on the substrate.

4. The thin film deposition system of claim 1,
further comprising means for controlling against cross-flow of material between the partitioned chambers to prevent contamination of material source and/or deposited material on the substrate.

5. The thin film deposition system of claim 4,
wherein the partition wall has an internal flow channel in fluidic communication with the chambers, and the means for controlling against cross-flow of material includes means for evacuating the chambers via the internal flow channel of the partition wall.

6. The thin film deposition system of claim 4,
wherein the partition wall has an internal flow channel in fluidic communication with the chambers, and the means for controlling against cross-flow of material includes means for flowing inert gas into the chambers via the internal flow channel of the partition wall.

7. The thin film deposition system of claim 1,
further comprising at least one additional chamber and material source, wherein the first, second and additional chambers are each partitioned from adjacent chambers by partition walls, the additional material source is arranged to introduce additional material to a substrate as it passes through the additional chamber, and the substrate conveyer is adapted to cyclically convey a substrate between the chambers so that the first, second, and additional materials are serially introduced to the substrate per cycle in isolation of each other for layer-by-layer deposition and/or reaction on the substrate.

8. The thin film deposition system of claim 1,
wherein the second material provided by the second material source is of a type known to react with the first material so that each cycle forms a compound layer on the substrate.

9. The thin film deposition system of claim 8,
wherein the first material provided by the first material source is a metal, and the second material provided by the second material source is oxygen or nitrogen, so that each cycle deposits on the substrate a metal layer followed by exposure to the oxygen or nitrogen to react with the metal layer to form an oxide or nitride layer, respectively.

10. The thin film deposition system of claim 9,
wherein the first material provided by the first material source is an atomic metal, and the second material provided by the second material source is atomic oxygen or nitrogen, so that the oxide or nitride layer formed per cycle is a fully oxidized or nitridized atomic monolayer.

11. The thin film deposition system of claim 8,
further comprising means for controlling against cross-flow of the reactive second material into the first chamber to prevent contamination of the first material source and/or deposited first material on the substrate.

12. A thin-film deposition method comprising:
providing first and second chambers partitioned from each other by a partition wall; a first material source arranged to introduce a first material to a substrate as it passes through the first chamber; and a second material source arranged to introduce a second material to a substrate as it passes through the second chamber; and
cyclically conveying a substrate between the first and second chambers so that the first and second materials are serially introduced to the substrate per cycle in isolation of each other for layer-by-layer deposition and/or reaction on the substrate.

13. The thin film deposition method of claim 12,
wherein the cyclically conveying step includes rotating about a rotation axis a substrate that is radially spaced from the rotation axis so as to be cyclically conveyed between the first and second chambers.

14. The thin film deposition method of claim 12,
further comprising providing a first channeling structure positioned in the first chamber and connected to receive the first material from the first material source and channel the first material to an outlet of the first channeling structure a substrate conveyance path; and a second channeling structure positioned in the second chamber and connected to receive the second material from the second material source and channel the second material to an outlet of the second channeling structure adjacent the substrate conveyance path, and
wherein the cyclically conveying step includes passing the substrate across the outlets of the channeling structures so that the first and second materials are serially introduced directly to the substrate per cycle in further isolation of each other for layer-by-layer deposition and/or reaction on the substrate.

15. The thin film deposition method of claim 12,
further comprising controlling against cross-flow of material between the partitioned chambers to prevent contamination of material source and/or deposited material on the substrate.

16. The thin film deposition method of claim 15,
wherein the partition wall has an internal flow channel in fluidic communication with the chambers, and the controlling against cross-flow of material step includes evacuating the chambers via the internal flow channel of the partition wall.

17. The thin film deposition method of claim 15,
wherein the partition wall has an internal flow channel in fluidic communication with the chambers, and the controlling against cross-flow of material step includes flowing inert gas into the chambers via the internal flow channel of the partition wall.

18. The thin film deposition method of claim 12,
further comprising providing at least one additional chamber and material source, wherein the first, second and additional chambers are each partitioned from adjacent chambers by partition walls, the additional material source is arranged to introduce additional material to a substrate as it passes through the additional chamber, and
wherein cyclically conveying step cyclically conveys the substrate between the chambers so that the first, second, and additional materials are serially introduced to the substrate per cycle in isolation of each other for layer-by-layer deposition and/or reaction on the substrate.

19. The thin film deposition method of claim 12,
wherein the second material provided by the second material source is of a type known to react with the first material so that each cycle forms a compound layer on the substrate.

20. The thin film deposition method of claim 19,
wherein the first material provided by the first material source is a metal, and the second material provided by the second material source is oxygen or nitrogen, so that each cycle deposits on the substrate a metal layer followed by exposure to the oxygen or nitrogen to react with the metal layer to form an oxide or nitride layer, respectively.

21. The thin film deposition method of claim 20,
wherein the first material provided by the first material source is an atomic metal, and the second material provided by the second material source is atomic oxygen or nitrogen, so that the oxide or nitride layer formed per cycle is a fully oxidized or nitridized atomic monolayer.

22. The thin film deposition method of claim 19,
further comprising controlling against cross-flow of the reactive second material into the first chamber to prevent contamination of the first material source and/or deposited first material on the substrate.
